(19) United States
(12) Patent Application Publication
(10) Pub. No.: US 2007/0007578 A1
(43) Pub. Date: Jan. 11, 2007

(54) Sub zero spacer for shallow MDD junction to improve BVDSS in NVM bitcell

(76) Inventors: Chi Nan Brian Li, Austin, TX (US); Cheong Min Hong, Austin, TX (US)

Correspondence Address: HAMILTON & TERRILE, LLP, P.O. BOX 203518, AUSTIN, TX, 78720, US

(21) Appl. No.: 11/176,765

(22) Filed: Jul. 7, 2005

(51) Int. Cl. H01L 29/788

(52) U.S. Cl. 257/315

(57) ABSTRACT

A semiconductor process and apparatus includes forming a floating gate stack structure (1) and a low voltage transistor gate stack structure (2) over a substrate (11) by including a shallow extension implant region (51, 52) that is aligned with the floating gate (13). By using a spacer etch process after a deep dielectric isolation (DDI) oxidation step is used to isolate the floating gate (13), a sub-zero spacer (31, 32) may be formed for the shallow extension implant (41, 42) which is subsequently diffused to overlap with the floating gate (13).

### BACKGROUND OF THE INVENTION

1. Field of the Invention

The present invention is directed in general to the field of semiconductor devices. In one aspect, the present invention relates to floating gate semiconductor memory devices.

2. Description of the Related Art

With non-volatile (NVM) memory devices shrinking in size, the shorter channel lengths of the smaller devices increasingly exhibit short channel behavior which affects program operation. For example, with ONO (oxide-nitride-oxide) based NVM cells, hot-carrier electron injection (HCI) into the floating gate is used to program a memory cell by applying a high drain voltage (Vd) on the selected bit line that exceeds a threshold voltage (Vt). However, if the drain voltage Vd exceeds the drain-to-source supply breakdown voltage (BVdss), the NVM bitcell transistor can be permanently damaged because it is incapable of sustaining the large breakdown current. As the NVM devices shrink, the BVdss also reduces, resulting in increased column leakage current when the same programming voltage Vd is applied at the selected bit line. The increased leakage current can load down the bit line driver and can increase power consumption. In a worst case, the intrinsic drain voltage Vd can be pulled down and the program efficiency can degrade. Prior efforts to increase the BVdss have increased the drive current requirements and have resulted in higher column leakage current.

Accordingly, a need exists for a memory cell with increased BVdss that maintains the same drive current. In addition, there is a need for a memory cell with reduced leakage current and improved programming efficiency. There is also a need for improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a partial cross-sectional view of an semiconductor device including a substrate, an etched NVM gate stack and an unetched low voltage transistor gate stack;

FIG. 2 illustrates processing subsequent to FIG. 1 after extension spacers are formed on the etched NVM gate stack;

FIG. 3 illustrates processing subsequent to FIG. 2 in which the extension spacers have been etched on the etched NVM gate stack;

FIG. 4 illustrates processing subsequent to FIG. 3 after implantation of a shallow MDD extension around the etched NVM gate stack;

FIG. 5 illustrates processing subsequent to FIG. 4 after the low voltage transistor gate stack is etched;

FIG. 6 illustrates processing subsequent to FIG. 5 after diffusion of the MDD implants that occurs during poly oxidation of the low voltage transistor gate stack;

FIG. 7 illustrates processing subsequent to FIG. 6 after low voltage extension spacers are formed on the etched NVM gate stack and the low voltage transistor gate stack and after an implantation of an extension region around the etched low voltage transistor gate stack;

FIG. 8 illustrates processing subsequent to FIG. 7 after source/drain spacers are formed on the etched NVM gate stack and the low voltage transistor gate stack;

FIG. 9 illustrates processing subsequent to FIG. 8 after implantation of source/drain regions around the etched NVM gate stack and the etched low voltage transistor gate stack; and

FIG. 10 illustrates processing subsequent to FIG. 9 whereby a floating gate memory device is formed.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for fabricating a non-volatile memory bitcell with improved breakdown voltage and reduced leakage current by including a shallow extension implant region that is aligned with the floating gate. By using a spacer etch process after a deep dielectric isolation (DDI) oxidation step is used to isolate the floating gate, a sub-zero spacer may be formed for the shallow extension implant, either alone or as part of the low voltage transistor fabrication process. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid obscuring the present invention. Such descriptions and representations are used by those skilled in the art to describe and convey the substance of their work to others skilled in the art.

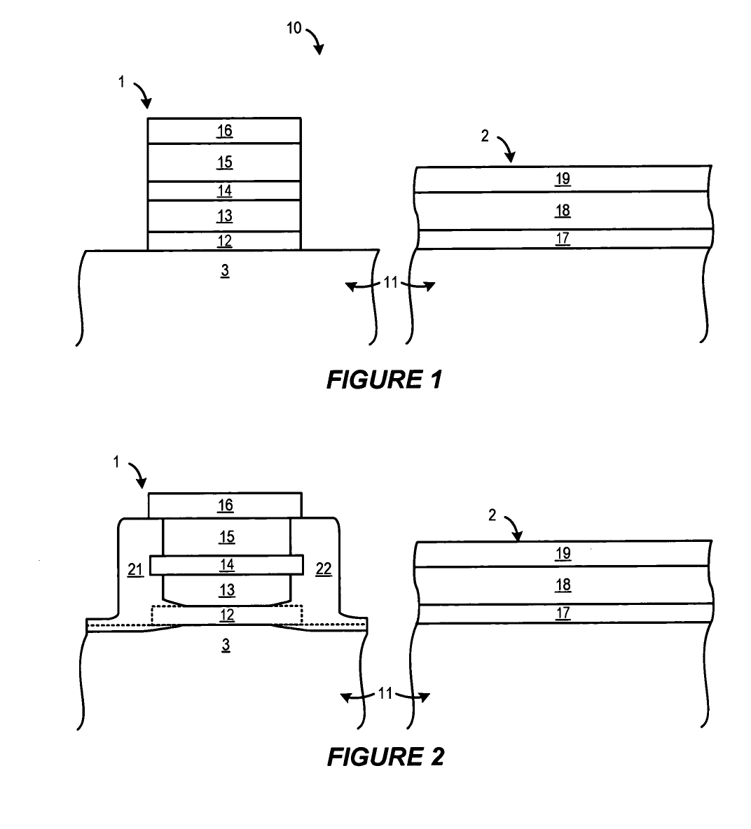

There is disclosed a method and apparatus for fabricating a semiconductor device which may be used as a NVM memory cell using floating gate extension spacers for implantation of a shallow medium doped drain (MDD) region that substantially aligns with the floating gate, thereby increasing BVdss for the NVM cell. The improved performance resulting from such a process may advantageously be incorporated with CMOS process technology which is used to build low voltage NMOS and PMOS devices. Various illustrative embodiments of the present invention will now be described in detail with reference to FIGS. 1-10. It is noted that, throughout this detailed description, certain layers of materials will be deposited and removed to form the depicted semiconductor structures. Where the specific procedures for depositing or removing such layers are not detailed below, conventional techniques to one skilled in the art for depositing, removing or otherwise forming such layers at appropriate thicknesses shall be intended. Such details are well known and not considered necessary to teach one skilled in the art of how to make or use the present invention.

FIG. 1 is a partial cross-sectional view of a semiconductor device 10 after formation of etched NVM gate stack structure 1 over a substrate 11, at which time an unetched low voltage transistor gate stack 2 is also formed over the substrate 11. Depending on the type of transistor device being fabricated, the substrate 11 may be implemented as a bulk silicon substrate, single crystalline silicon (doped or undoped), or any semiconductor material including, for example, Si, SiC, SiGe, SiGeC, Ge, GaAs, InAs, InP as well as other Group III-IV compound semiconductors or any combination thereof, and may optionally be formed as the bulk handling wafer. In addition, the substrate 11 may be implemented as the top silicon layer of a silicon-on-insulator (SOI) structure.

As depicted, gate stack structure 1 defines a channel region 3 for a non-volatile memory device, and includes a first insulating layer or tunnel dielectric 12 that is formed over channel region 3, a floating gate 13 formed over the tunnel dielectric 12, an ONO (oxide-nitride-oxide) stack 14 formed over the floating gate 13, a control gate 15 formed over the ONO stack 14, and an anti-reflective coating (ARC) layer 16 formed over the control gate 15. In forming gate stack structure 1, a tunnel dielectric layer 12 is formed by depositing or growing a dielectric (e.g., silicon dioxide, oxynitride, metal-oxide, nitride, etc.) over the semiconductor substrate 11 using chemical vapor deposition (CVD), plasma-enhanced chemical vapor deposition (PECVD), physical vapor deposition (PVD), atomic layer deposition (ALD), thermal oxidation, or combinations of the above. A floating gate layer 13 acts as a charge storage layer for the floating gate device, and may be formed from any conductive material (e.g., polysilicon, metal, or the like) that is blanket deposited over the tunnel dielectric layer 12 by CVD, PECVD, PVD, ALD, or combinations thereof. As will be appreciated, there are other types of non-volatile memory devices besides floating gate devices, including nanocluster devices and SONOS (silicon-oxide-nitride-oxide-silicon) devices. With these other NVM devices, the charge storage function may be implemented with a layer formed from a plurality of nanoclusters or nanocrystals (i.e. discrete storage elements), such as in the case of a nanocrystal NVM device, or may be implemented with a layer formed from a nitride layer, such as in the case of a SONOS NVM device.

Referring back to the floating gate example depicted in FIG. 1, an ONO stack 14 is formed by sequentially depositing and/or growing a first oxide layer, a nitride layer and a second oxide layer. In the floating gate device, the ONO stack 14 acts as a control dielectric layer. The oxide layers in the ONO stack 14 can be any dielectric, such as, for example, an insulating material or stack of insulating materials, such as, for example, silicon oxide, oxynitride, metal-oxide, nitride, etc., or any combination thereof. The nitride layer in the ONO stack 14 may be a silicon nitride, oxynitride, or any other dielectric or insulating material. After formation of the ONO stack 14, a control gate layer 15 is then deposited over the ONO layer 14 by CVD, PECVD, PVD, ALD, or combinations thereof. Control gate 15 may be formed of any conductive material, such as polysilicon or a metal-containing material. Finally, the ARC layer 16 is formed over the control gate layer 15. Using conventional masking and etch processes, the previously formed layers may then be patterned and etched to form the resulting gate stack structure 1. As will be appreciated, each layer of the stack may be patterned and etched individually to form the resulting gate stack structure 1. In one embodiment, the resulting gate stack structure 1 (and likewise, the portion of channel region 3 below gate stack 1) has a length in a range of approximately of 0.05 microns to 5 microns, and in a selected embodiment, the channel length of the gate stack structure 1 is approximately 1 micron.

At the stage in the fabrication of the semiconductor device 10 depicted in FIG. 1, an unetched gate stack 2 for the low voltage transistor devices is also formed over the substrate 11. The unetched low voltage transistor gate stack 2 includes a gate dielectric 17 formed over substrate 11. The gate dielectric 17 may be formed separately from the tunnel dielectric layer 12. The unetched gate stack 2 also includes a polysilicon layer 18, which may be formed at the same time and with the same materials as the control gate 15, or may be formed from any suitable conductive layer, such as polysilicon, metal, or the like. As will be appreciated, a metal layer (not shown) may be used in place of the polysilicon layer 18 for the low voltage transistor device. Finally, the ARC layer 19 is formed over the poly layer 18.

FIG. 2 illustrates processing of the semiconductor device 10 subsequent to FIG. 1 after extension spacers 21, 22 are formed on the etched NVM gate stack 1. As will be appreciated, the extension spacers 21, 22 may be formed as a single continuous spacer that is formed on the exposed lateral sidewalls of the etched NVM gate stack 1, though the extension spacers may also be formed as separate spacers structures or may be referred to separately even though formed as part of a single continuous spacer structure. While the extension spacers may be formed by a dielectric layer deposition process, FIG. 2 shows the extension spacers 21, 22 as being formed by an oxidation process known as a deep dielectric isolation (DDI) that serves to form a protective layer of oxide on the sides of the floating gate 13 and control gate 15 for the purpose of protecting the exposed ends of the material that will form the floating gate 13 and the control gate 15. As illustrated, the oxidation process consumes part of the floating gate and control gate layers 13, 15, but does not affect the ONO stack 14 or ARC layer 16. Alternatively, the extension spacers 21, 22 may be fabricated with one or more thin layers of grown oxide in combination with one or more deposited oxide layers. By forming the extension spacers with a thinner grown layer of oxide, the resulting lifting of the floating gate edges as shown FIG. 2 may be reduced. In addition, the amount of oxide that forms underneath the tunneling dielectric layer 14 is reduced. The dashed lines shown in FIG. 2 illustrate the original outline of the substrate 11 and tunnel dielectric layer 14. As shown in FIG. 2, the ARC layer 19 effectively protects the underlying layers of the unetched low voltage transistor gate stack 2 from the DDI oxidation step.

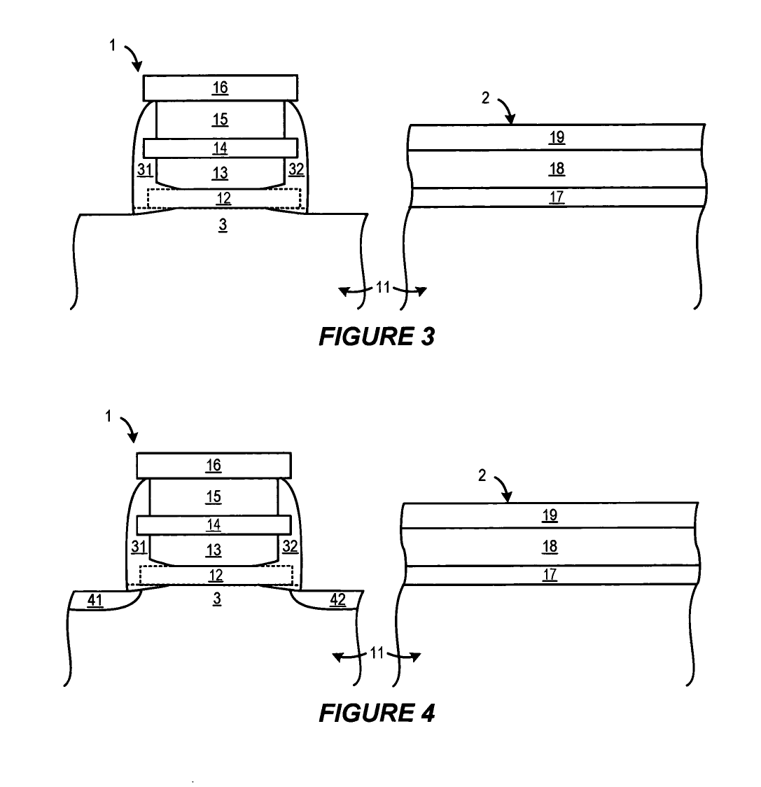

FIG. 3 illustrates processing of the semiconductor device 10 subsequent to FIG. 2 in which at least selected portions of the extension spacers 21, 22 have been etched to form extension sidewall spacers 31, 32 on the exposed sidewalls of the floating gate 13 of the etched NVM gate stack 1. Depending on the constituent materials and dimensions of the original extension spacers 21, 22, the etching may use one or more anisotropic etch processes to form extension sidewall spacers 31, 32, including a dry etching process (such as reactive-ion etching, ion beam etching, plasma etching, laser etching), a wet etching process (wherein a chemical etchant is employed) or any combination thereof. At this stage, surface of the substrate 11 is exposed to allow subsequent implantation of the MDD extension dosage to be implanted in the S/D area. As depicted, the underlying layers of the unetched low voltage transistor stack 2 are protected from the sidewall spacer etch process by the ARC layer 19. As a result, the spacer formed on the floating gate stack 1 is not formed as part of the low voltage transistor fabrication process, and may be referred to as a sub-zero spacer, where subsequent spacers formed on both the floating gate and low voltage transistor stacks are referred to as a “zero spacer” or a “spacer,” as described below.

FIG. 4 illustrates processing of the semiconductor device 10 subsequent to FIG. 3 after ion implantation of shallow MDD extension regions 41, 42 around the etched NVM gate stack. At this stage in the process, conventional implanting processes may be used to implant the source and drain extensions 41, 42 with ions having a predetermined conductivity type by implanting the ions around the extension sidewall spacers 31, 32, while the ARC layer 19 protects the low voltage transistor stack 2 from the implantation step. As implanted, the extensions 41, 42 extend toward the channel region 3 but do not yet align with the edges of the floating gate stack 1. In other words, there is less lateral straggle under the floating gate stack 1 when the sub-zero spacers are used in forming the MDD extension regions. In one embodiment, an N-type dopant, such as arsenic, phosphorous, or antimony, is implanted at an energy in a range of approximately 1 to 20 keV having a dosage in a range of approximately 5×10¹³/cm² to 1×10¹⁵/cm² to form MDD extension regions 41, 42. At this point in the fabrication process, a halo region may also be formed by implanting an N-type dopant at an energy in a range of approximately 1 to 20 keV having a dosage in a range of approximately 1×10¹²/cm² to 1×10¹⁴/cm². If a halo region is formed on the drain side, the MDD extension on the drain side is formed such that it does not extend beyond halo region. As will be appreciated, the implantation of dopants to form the MDD regions may be done in one or more steps, and the source and drain extensions 41, 42 may also be formed with separate implantation steps, such as when different ions are used to form each region.

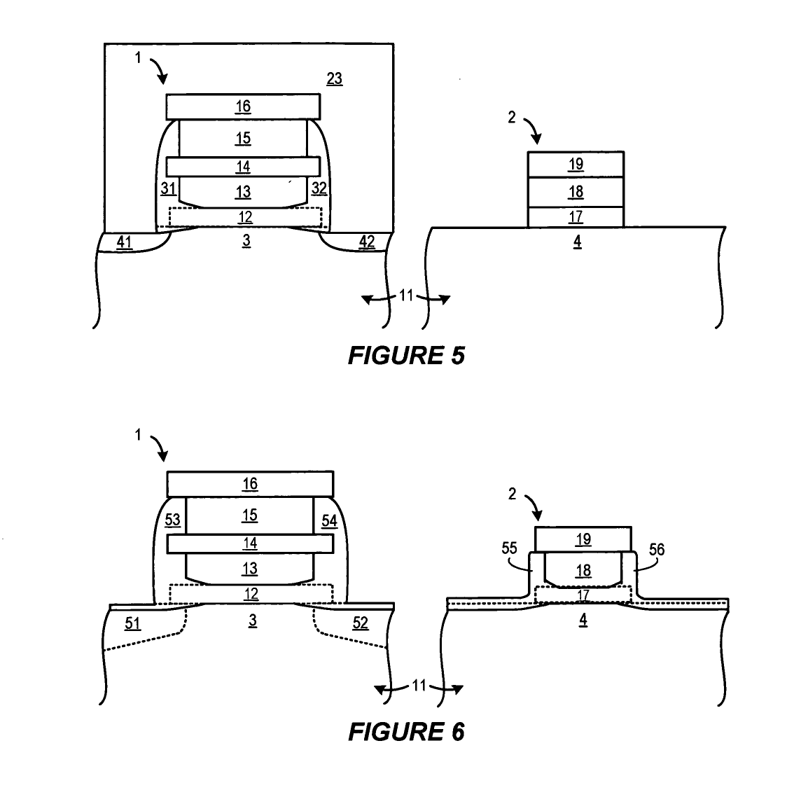

FIG. 5 illustrates processing subsequent to FIG. 4 after the low voltage transistor gate stack is etched to form an etched gate stack structure 2 which defines a channel region 4 in the substrate 11. The etched gate stack structure 2 includes a gate dielectric 17 formed over channel region 4, a polysilicon or metal gate layer 18 formed over the gate dielectric 17, and an ARC layer 19 formed over the poly gate layer 18. At this stage in the process, a patterned mask layer 23 is formed over the NVM gate stack 1 using any desired technique, such as, for example, a photo resist layer, a hard mask, etc.

FIG. 6 illustrates processing of the semiconductor device 10 subsequent to FIG. 4 after diffusion of the MDD implants 41, 42 to form MDD extension regions 51, 52. At this stage, an anneal process drives or diffuses the implanted MDD ions into the substrate 11 to form the diffused MDD source and drain regions 51, 52 so that the MDD regions 51, 52 extend into the channel region 3 for substantial alignment with the edges of the floating gate 13 in the floating gate stack 1. In one embodiment, the time, temperature and other conditions for the anneal process are selected to optimize the position of the MDD extension junctions for purposes of HCI efficiency, such as by using an rapid thermal anneal process which heats the semiconductor device 10 with a temperature ramp up (e.g., 50 degrees per second) to a target temperature of 1000 degrees where the temperature is maintained for 5-20 seconds, followed by a rapid temperature ramp down.

In accordance with a selected embodiment, the MDD extension anneal process occurs during poly oxidation of the etched low voltage transistor gate stack 2. As illustrated in FIG. 6, the poly oxidation step occurs after the mask layer 23 is removed from the etched NVM gate stack using any desired mask removal process. When the poly oxidation step that is used to grow oxide on the polysilicon gate layer 18 is performed at an elevated temperature, this heating step acts to anneal the MDD implant regions 51, 52, thereby repairing any substrate damage created by the sub-zero spacer etch or the implantation of MDD dopant ions. The poly oxidation also causes a layer of oxide 55, 56 to grow on the exposed sides of the polysilicon gate layer 18, and increases the thickness of the sidewall extension spacers 53, 54. As will be appreciated, the extension spacers 53, 54 are formed by growing additional oxide at the interface between the extension sidewall spacers 31, 32 and the underlying etched NVM gate stack 1, and may be formed as a single continuous spacer around the exposed lateral sidewalls of the etched NVM gate stack 1, though the extension spacers 53, 54 may also be formed as separate spacers structures or may be referred to separately even though formed as part of a single continuous spacer structure. In addition, the poly oxidation process causes gate edge lifting on both the floating gate and low voltage transistor stacks. The dashed lines show the original outline of the silicon substrate 11, the tunneling dielectric 12 and the gate dielectric 17. The increased gate edge lifting at the gate stacks reduces the electric field strength at the gate edges and acts to reduce the effects of hole trapping, thereby improving device reliability.

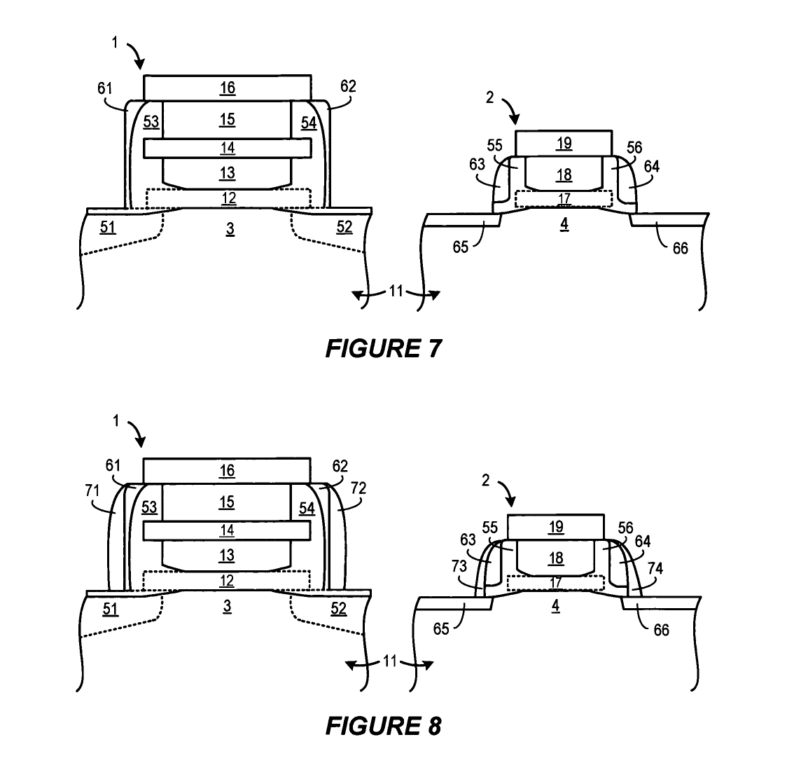

FIG. 7 illustrates processing of the semiconductor device 10 subsequent to FIG. 6 after formation of floating gate stack spacers 61, 62 and low voltage transistor stack spacers 63, 64, and after implantation of extension regions 65, 66 for the low voltage transistor device. As will be appreciated, the spacers 61, 62, 63, 64 formed on each etched stack may be formed as a single continuous spacer that is formed on the lateral sidewalls of the etched stack, though the spacers may also be formed as separate spacers structures or may be referred to separately even though formed as part of a single continuous spacer structure. As illustrated, the spacers 61, 62, 63, 64 may be formed by depositing any desired dielectric material (such as oxide or nitride) and then selectively etching the deposited material using one or more anisotropic etch processes to form extension sidewall spacers 61, 62, 63, 64. Thus, on the floating gate stack structure 1, the spacers 61, 62 are formed on the sidewall extension spacers 53, 54. Suitable spacer etch processes include dry etching, wet etching process or any combination thereof. Alternatively, a layer of dielectric material may be grown (such as by using an oxidation process to form an additional layer of oxide on the sides of the floating gate 13, control gate 15 and polysilicon gate 18 and on the exposed surface of the substrate 11) and etched to form extension sidewall spacers 61, 62, 63, 64. The use of a dielectric growth process consumes the polysilicon in the gate stacks 1, 2 and substrate and increases the lifting effect at the gate edges, but also reoxidizes the floating gate layer 13 to improve or maintain electrical isolation after the sub-zero spacer etch process. Because the spacers 63, 64 are used for implantation of the extension regions 65, 66 in the low voltage transistor devices, the spacers 61, 62, 63, 64 may be referred to as low voltage extension spacers or zero spacers since this is the first spacer used for implantation of the low voltage transistor devices.

After formation of the spacers 61, 62, 63, 64 and before implantation of the extension regions 65, 66, a masking layer (not shown) may optionally be formed to protect the stack 1 from the low voltage extension implant step. At this stage, source and drain extensions 65, 66 for the low voltage transistor devices may be formed using any desired implantation processes to form the source and drain extensions 65, 66 around the low voltage extension spacers 63, 64, alone or in combination with any remaining poly oxide sidewall layers 55, 56. The source and drain extensions 65, 66 may be formed by implanting ions around the sidewall spacers into a predetermined source/drain extension region for the low voltage transistor devices. As implanted, the low voltage extensions 65, 66 extend toward the channel region 4 but do not yet align with the edges of the polysilicon gate 18 in the low voltage transistor gate stack 2. In one embodiment, an N-type dopant, such as arsenic, phosphorous, or antimony, is implanted at an energy in a range of approximately 1 to 10 keV having a dosage in a range of approximately 5×10¹³/cm² to 5×10¹⁵/cm² to form extensions 65 and 66. As will be appreciated, the implantation of dopants to form the low voltage extension regions may be done in one or more steps, and the source and drain extensions 65, 66 may also be formed with separate implantation steps, such as when different ions are used to form each region.

FIG. 8 illustrates processing of the semiconductor device 10 subsequent to FIG. 7 after source/drain spacers 71, 72, 73, 74 are formed on the flash memory device and the low voltage transistor device. Again, the spacers 71, 72, 73, 74 formed on each etched stack may be formed as a single continuous spacer that is formed on the lateral sidewalls of the etched stack, though the spacers may also be formed as separate spacers structures or may be referred to separately even though formed as part of a single continuous spacer structure. As illustrated, the spacers 71, 72, 73, 74 may be formed by depositing any desired dielectric material (such as oxide or nitride) and then selectively etching the deposited material using any suitable etch processes to form extension sidewall spacers 71, 72, 73, 74. Alternatively, a layer of dielectric material may be grown (such as by using an oxidation process to form an additional layer of oxide on the sides of the floating gate 13, control gate 15 and polysilicon gate 18 and on the exposed surface of the substrate 11) and etched to form extension sidewall spacers 71, 72, 73, 74. Again, the use of a dielectric growth process consumes the polysilicon in the gate stacks 1, 2 and substrate and increases the lifting effect at the gate edges. Because the spacers 71, 72, 73, 74 are used for implantation of the deep source/drain regions (described below) in the low voltage transistor devices, the spacers 71, 72, 73, 74 may be referred to as source/drain spacers or simply “spacers” since this spacer is used for implantation of the deep (N+ or P+) regions in the floating gate and low voltage transistor devices.

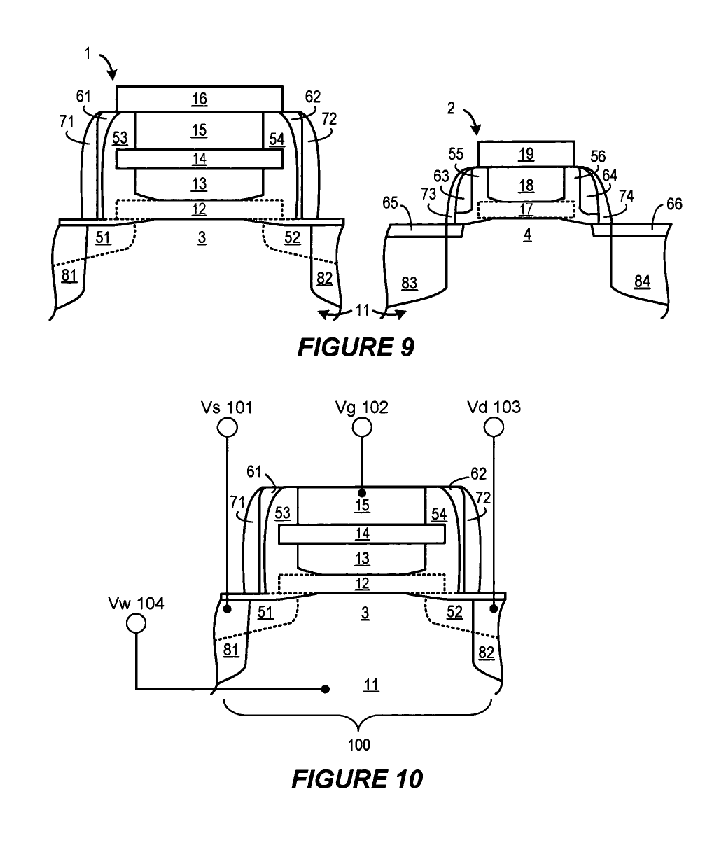

FIG. 9 illustrates processing of the semiconductor device 10 subsequent to FIG. 8 after implantation of source/drain regions 81, 82, 83, 84 for the flash memory device and the low voltage transistor device. In particular, after formation of source/drain spacers 71, 72, 73, 74, deep source/drain regions 81, 82, 83, 84 for the flash memory device and the low voltage transistor devices may be formed using any desired implantation processes to form the deep source/drain regions 81, 82, 83, 84 around the low voltage source/drain spacers 71, 72, 73, 74, alone or in combination with any remaining portions of previously formed sidewall spacers. In one embodiment, an N-type dopant, such as arsenic, phosphorous, or antimony, is implanted at an energy in a range of approximately 10 to 30 keV having a dosage in a range of approximately 5×10¹⁴/cm² to 5×10¹⁶/cm² to form source region and drain regions 81, 82, 83, 84. As will be appreciated, the implantation of dopants to form the deep source/drain regions 81, 82, 83, 84 may be done in one or more steps, and the source and drain deep source/drain regions 81, 82, 83, 84 may also be formed with separate implantation steps, such as when different ions are used to form each region. As implanted, the deep source/drain regions 81, 82, 83, 84 are positioned to spaced away from the channel regions 3, 4 in order to reduced hot carrier injections problems. Any subsequent annealing step, such as a rapid thermal anneal process, should be chosen to maintain the relative position of the deep regions in relation to the channel so that the deep implant source and drain regions are spaced away from the edges of the floating gate stack structure.

Additional processing steps may be used to complete the fabrication of the floating gate and low voltage transistor devices into functioning transistors. As examples, one or more sacrificial oxide formation, stripping, isolation region formation, extension implant, halo implant, spacer formation, source/drain implant, and polishing steps may be performed, along with conventional backend processing (not depicted) typically including formation of multiple levels of interconnect that are used to connect the transistors in a desired manner to achieve the desired functionality. Thus, the specific sequence of steps used to complete the fabrication of the floating gate and low voltage transistor devices may vary, depending on the process and/or design requirements. Also, other semiconductor device levels may be formed underneath or above semiconductor device 10.

Turning now to FIG. 10, a floating gate memory device 100 formed from the floating gate stack structure 1 and implanted source/drain regions may be programmed by applying appropriate programming voltages to the control gate, source and drain regions. As will be appreciated by those skilled in the art, the floating gate NVM memory device 100 is programmed by storing electrons within the floating gate 13, which results in the floating gate device 100 having a high voltage (such as, for example, above approximately 4 volts). Therefore, floating gate device 100 may be programmed by applying a drain voltage (Vd) 103 to the drain region 82, 52 and a source voltage (Vs) 101 to the source region 81, 51, where Vd is approximately 3 to 5 volts greater than Vs. For example, in one embodiment, a source voltage Vs 101 of 1 volt and a drain voltage Vd 103 of 4 volts may be used. In this embodiment, a gate voltage (Vg) 102 of approximately 5 to 10 volts is applied to the control gate 15, and a well voltage (Vw) 104 of approximately 0 to −3 volts is applied to a well region (not shown) or substrate 11. As will be appreciated, the voltages in this example are provided with reference to the source voltage (Vs) 101. That is, in this example, if Vs is increased by 1 volt, Vd, Vg, and Vw are also increased by 1 volt. During the programming of floating gate device 100 with the above voltages applied, hot carriers are generated in the drain depletion region, some of which are injected through tunnel dielectric 12 into the floating gate 13. This results in increasing the voltage of the floating gate 13 in the floating gate device 100. In accordance with selected embodiments of the present invention, the formation of the MDD drain extension region 52 amplifies this hot carrier injection, thus maintaining efficient hot carrier programming of floating gate device 100.

If the drain to source supply breakdown voltage (BVdss) is too low (such as, for example, due to the counter doping of channel region 3), a source to drain leakage current can occur during programming of the floating gate device 100. The inclusion of the MDD extension regions effectively increases the drain to source supply breakdown voltage (BVdss) of the floating gate device 100 without also increasing the drive current requirements for programming the floating gate device 100. For example, using sub-zero spacers to form MDD extension regions can increase the BVdss from 0.5-1 volts over fabrication processes that do not use a sub-zero spacer to form MDD extension regions.

Yet another possible advantage of the present invention is that the non-volatile memory cell that includes MDD extension regions formed with sub-zero spacers have lower a natural threshold voltage Vt to minimize threshold voltage drift during a read cycle. With a lower natural threshold voltage Vt, erase speed and low temperature data retention (LTDR) leakage can be improved.

In one form, there is provided herein a method for fabricating a non-volatile memory device by forming a shallow MDD junction in a floating gate device with substantial gate-to-drain alignment in order to increase BVdss. By using a spacer etch process after a DDI oxidation process, a sub-zero spacer is formed in the process of oxidizing the floating gate. The sub-zero spacer oxide surrounding the floating gate provides good electrical isolation of floating gate and good data retention. By etching the sub-zero spacer, the bare substrate surface is exposed to allow enough MDD extension dosage to be implanted in the source/drain area. The implanted MDD extensions are subsequently diffused beyond the sub-zero spacers to connect to the channel region, thereby preserving program efficiency while annealing any damage created by the sub-zero spacer etch or implantation steps. Subsequently formed spacers (such as used in the formation of low voltage transistor devices) may include a reoxidation step to further oxidize the floating gate, thereby improving or repairing electrical isolation after the sub-zero spacer etch.

In another form, a method is provided for forming a non-volatile memory semiconductor device by forming a first insulating layer over a semiconductor substrate and then forming a floating gate stack structure over the first insulating layer. For example, a floating gate stack structure may include a control gate layer formed over a control dielectric which is formed over a charge storage layer made with polysilicon. Next, one or more first sidewall or subzero spacers are formed on the floating gate stack structure by growing a sidewall dielectric layer on the exposed sidewalls of a floating gate layer in the floating gate stack structure and then anisotropically etching the sidewall dielectric layer. In a selected embodiment, the growth of the sidewall dielectric layer occurs as part of a poly oxidation step that is used to oxidize a low voltage polysilicon gate structure on another part of the semiconductor substrate. These subzero spacers are used as implant masks during implantation of the source and drain extension regions with implant ions having a predetermined conductivity type into a first region of the semiconductor substrate. The implanted source and drain extension regions, sometimes referred to as MDD extension regions, may be subsequently diffused into substantial alignment and/or overlap with the sidewalls of the floating gate layer. One or more second sidewall spacers are subsequently formed on the first sidewall spacer, and are used as implant masks during implantation of the source and drain regions with implant ions having a predetermined conductivity type into a second region of the semiconductor substrate. In a selected embodiment, the formation of the second sidewall spacers occurs as part of a spacer formation step that is used to form sidewall spacers on a low voltage polysilicon gate structure on another part of the semiconductor substrate.

In another form, a method is provided for manufacturing flash memory devices. Under the method, a gate stack structure is formed on a substrate, where the gate stack structure includes a tunnel oxide formed on the substrate, a floating gate formed on the tunnel oxide, a layer of dielectric formed on the floating gate and a control gate formed on the layer of dielectric. Next, a first layer of oxide is formed on exposed portions of the floating gate stack structure (e.g., using a deep dielectric isolation oxidation process), thereby electrically isolating the floating gate. The first layer of oxide may then be etched to form a first sidewall spacer on the floating gate stack structure. The first sidewall spacer is then used during implantation of a first type of ions around the first sidewall spacer and into a first region of the substrate, thereby forming first MDD extension regions for the flash memory device. Subsequently, one or more second sidewall spacers are formed on the floating gate stack structure, and a second type of ions is implanted around the second sidewall spacer and into a second region of the substrate to form deep implant source and drain regions for the flash memory device. In a selected embodiment, the second sidewall spacers may be formed simultaneously with the formation of sidewall spacers on a low voltage transistor device that is located on another part of the substrate. In addition, the implantation of the second type of ions may occur as part of a ion implantation step that is used to form deep source/drain regions on a low voltage transistor device on another part of the semiconductor substrate. Through an annealed process, the first extension regions are diffused laterally so that there is substantial gate-to-drain alignment and/or overlap with the floating gate stack structure. For example, the anneal step can occur as part of the oxidization of the floating gate stack structure after implanting the first type of ions, and/or can occur as part of an oxidization of a low voltage polysilicon gate structure on another part of the substrate.

In another form, a non-volatile memory device and fabrication process is provided. As formed, a gate stack structure defining a channel region in a substrate includes a tunnel oxide formed on the substrate, a floating gate formed on the tunnel oxide, a layer of dielectric formed on the floating gate and a control gate formed on the layer of dielectric. First sidewall spacers formed on sidewall surfaces of the gate stack structure are used in the implantation of first medium doped drain extension regions that are implanted around the first sidewall spacers and substantially aligned with the gate stack structure. The first sidewall spacers may be formed by oxidizing the gate stack structure to form a first oxide layer that electrically isolates the floating gate and then etching the first oxide layer to form the first sidewall spacers. Second sidewall spacers may be formed as two or more additional sidewall spacers on the first sidewall spacers. With second sidewall spacers formed on the first sidewall spacers, deep source and drain regions may be implanted around the second sidewall spacers and diffused so as to be spaced apart from the channel region. The fabrication of the non-volatile memory device may be integrated with the fabrication process for forming low voltage transistor devices on the same substrate.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the gate stack 1 is illustrated as a floating gate device that includes an ONO stack for the control dielectric, though in alternate embodiments, gate stack may be any type of NVM gate stack, such as a SONOS (silicon-oxide-nitride -oxide-silicon) stack or a nanocluster stack. The depicted transistor structures may also be formed in a well region (not shown) of the substrate 111 which may be an n-doped well or a p-doped well. Also, the floating gate, control gate, and polysilicon gate layers may be formed with different conductive materials than those disclosed. In addition, the source and drains and extensions may be p-type or n-type, depending on the polarity of the underlying substrate or well region, in order to form either p-type or n-type semiconductor devices. Moreover, the thickness of the described layers may deviate from the disclosed thickness values. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for forming a non-volatile memory semiconductor device, comprising:
providing a semiconductor substrate;
forming a first insulating layer over the semiconductor substrate;
forming a floating gate stack structure over the first insulating layer, said floating gate stack structure comprising a floating gate layer;
forming a first sidewall spacer on the floating gate stack structure by growing a sidewall dielectric layer on exposed sidewalls of the floating gate layer;
forming source and drain extension regions by implanting ions having a predetermined conductivity type around the first sidewall spacer into a first predetermined region of the semiconductor substrate;
forming a second sidewall spacer on the first sidewall spacer; and
forming source and drain regions by implanting ions having a predetermined conductivity type around the first and second sidewall spacers into a second predetermined region of the semiconductor substrate.

2. The method of claim 1, wherein forming a floating gate stack structure comprises:
forming a charge storage layer over the first insulating layer;
forming a control dielectric layer over the charge storage layer; and
forming a control gate layer over the control dielectric layer.

3. The method of claim 2, wherein the charge storage layer comprises polysilicon.

4. The method of claim 1, further comprising anisotropically etching the first sidewall spacer prior to forming source and drain extension regions.

5. The method of claim 1, where a poly oxidation step used in oxidizing a low voltage polysilicon gate structure on another part of the semiconductor substrate is used to form the first sidewall spacer.

6. The method of claim 1, where a spacer formation step used in forming a third sidewall spacer on a low voltage polysilicon gate structure on another part of the semiconductor substrate is used to form the second sidewall spacer.

7. The method of claim 1, where forming source and drain extension regions comprises diffusing the implanted ions having a predetermined conductivity type into substantial alignment with the sidewalls of the floating gate layer.

8. The method of claim 1, where the source and drain extension regions overlap with the floating gate layer.

9. The method of claim 1, where the source and drain extension regions comprise MDD extension regions.

10. A method of manufacturing a flash memory device comprising:
forming a gate stack structure on a substrate wherein the gate stack structure comprises a tunnel oxide formed on the substrate, a floating gate formed on the tunnel oxide, a layer of dielectric formed on the floating gate and a control gate formed on the layer of dielectric;
forming a first layer of oxide on exposed portions of the floating gate stack structure and the substrate, thereby electrically isolating the floating gate;
etching the first layer of oxide to form a first sidewall spacer on the floating gate stack structure;
implanting a first type of ions around the first sidewall spacer and into a first region of the substrate to form first extension regions for the flash memory device;
forming at least a second sidewall spacer on the floating gate stack structure;
implanting a second type of ions around the second sidewall spacer and into a second region of the substrate to form deep implant source and drain regions for the flash memory device; and
annealing the flash memory device to obtain gate-to-drain overlap between the first extension regions and the floating gate stack structure.

11. The method of claim 10, where the first layer of oxide is formed using a deep dielectric isolation oxidation step to isolate the floating gate.

12. The method of claim 10, further comprising oxidizing the floating gate stack structure after implanting the first type of ions to align at least one of the first extension regions with an edge of the floating gate stack structure.

13. The method of claim 12, where the step of oxidizing the floating gate stack structure occurs while a low voltage polysilicon gate structure on another part of the substrate is oxidized.

14. The method of claim 10, where the step of implanting a second type of ions occurs while deep implant source and drain regions are implanted for a low voltage transistor device that is located on another part of the substrate.

15. The method of claim 10, where the step of forming at least a second sidewall spacer comprises forming two or more additional sidewall spacers on the floating gate stack structure.

16. The method of claim 15, where the step of forming two or more additional sidewall spacers simultaneously forms additional sidewall spacers on a low voltage transistor device that is located on another part of the substrate.

17. A non-volatile memory device, comprising:
a gate stack structure defining a channel region in a substrate, said gate stack structure comprising a tunnel oxide formed on the substrate, a floating gate formed on the tunnel oxide, a layer of dielectric formed on the floating gate and a control gate formed on the layer of dielectric;
first sidewall spacers formed on sidewall surfaces of the gate stack structure;
first medium doped drain extension regions that are implanted around the first sidewall spacers and substantially aligned with the gate stack structure;
second sidewall spacers formed on the first sidewall spacers; and
deep source and drain regions that are implanted around the second sidewall spacers and diffused so as to be spaced apart from the channel region.

18. The non-volatile memory device of claim 17, where the first sidewall spacers are formed by oxidizing the gate stack structure to form a first oxide layer that electrically isolates the floating gate and then etching the first oxide layer to form the first sidewall spacers.

19. The non-volatile memory device of claim 17, where the second sidewall spacers comprises two or more additional sidewall spacers formed on the first sidewall spacers.

20. The non-volatile memory device of claim 17, further comprising a first transistor device formed on the substrate, where the first transistor device comprises a low voltage polysilicon gate layer that is formed at the same time as the control gate is formed.
